(19) United States
(12) Patent Application Publication
(10) Pub. No.: US 2016/0351536 A1
(43) Pub. Date: Dec. 1, 2016

(54) BONDING APPARATUS AND BONDING TOOL CLEANING METHOD

(71) Applicant: Shinkawa Ltd., Tokyo (JP)

(72) Inventors: Toru Maeda, Tokyo (JP); Tetsuya Utano, Tokyo (JP)

(73) Assignee: Shinkawa Ltd., Tokyo (JP)

(21) Appl. No.: 15/233,394

(22) Filed: Aug. 10, 2016

Related U.S. Application Data
(63) Continuation of application No. 14/045,879, filed on Oct. 4, 2013.
Application No. 14/045,879 is a continuation of application No. PCT/JP2011/075484, filed on Nov. 4, 2011.

(30) Foreign Application Priority Data
Apr. 5, 2011 (JP) 2011-083547

(51) Int. Cl. H01L 23/00; B08B 7/00; B08B 7/02; B23K 20/00

(52) U.S. Cl. CPC H01L 24/85; B23K 20/004; H01L 24/78; B08B 7/0035; B08B 7/028; H01L 2224/85345; H01L 2224/78611; H01L 2224/7855; H01L 2224/7801; H01L 2224/85205; H01L 2224/78343; H01L 2224/45147; H01L 2224/45144; H01L 2224/45124

(57) ABSTRACT

In wire bonding in which a bonding tool is cleaned through plasma irradiation, the plasma application to a wire and therefore the formation of an unexpectedly large-sized ball in the following bonding operation is prevented. The cleaning of the bonding tool through plasma irradiation is followed by dummy bonding, the bonding tool is cleaned with a ball formed thereon, or a prohibition period is provided during which ball forming is prohibited until the energy of plasma attenuates after the bonding tool is cleaned to prevent the plasma irradiation from having an impact on the bonding operation so that the ball cannot have an increased diameter.

### BACKGROUND OF THE INVENTION

1. Technical Field

The present invention relates to a bonding apparatus having a feature of cleaning a tip portion of a bonding tool and also to a bonding tool cleaning method.

2. Related Art

In semiconductor device manufacturing processes, a bonding apparatus is used to connect pads on a semiconductor die placed on a lead frame and leads on the lead frame. Such a bonding apparatus includes a bonding tool called wedge tool or capillary and is arranged to use a wire inserted through the bonding tool to bond the pads on the semiconductor die and the leads on the lead frame.

The more the number of wires connected, the more foreign matters adhere to a tip portion of the bonding tool and the more inconveniences are likely to occur in bonding. In order to reduce such inconveniences, there has been developed a technique for cleaning foreign matters adhering to the tip portion of the bonding tool.

Japanese Unexamined Patent Application Publication No. 2008-21943 (Patent Document 1), for example, discloses a bonding apparatus in which a plasma torch is provided in a cleaning case into which a tip of a capillary can be inserted, plasma is jetted through a plasma jet port of the plasma torch to clean the tip portion of the capillary, and exhaust gas is discharged through a discharge port.

Japanese Unexamined Patent Application Publication No. 2008-218789 (Patent Document 2) discloses a wire bonding method in which a plasma irradiation unit is placed around a bonding target member and, prior to wire bonding to the bonding target member, a capillary is moved to the plasma irradiation unit and exposed to plasma irradiation, so that organic matters adhering to a tip portion of the capillary is removed.

### CONVENTIONAL ART DOCUMENTS

### Patent Documents

Patent Document 1: Japanese Unexamined Patent Application Publication No. 2008-21943
Patent Document 2: Japanese Unexamined Patent Application Publication No. 2008-218789

### SUMMARY OF THE INVENTION

However, the inventions disclosed in Japanese Unexamined Patent Application Publication Nos. 2008-21943 and 2008-218789 may suffer from various inconveniences such as electrical shorting between adjacent pads resulting from the diameter of deformed balls bonded at bonding positions exceeding a predetermined size during a bonding operation after cleaning the tip and the side surface of the bonding tool and/or may undergo a reduction in the bonding strength due to, for example, an increase in the thickness of the balls after bonding at the bonding positions.

It is hence an object of the present invention, in consideration of the above-described problems, to provide a bonding technique in which a bonding tool can be cleaned without increasing the diameter of deformed balls bonded at bonding positions.

The inventors of this application have conducted an earnest analysis to finally find out that the problems are caused by residual energy in the wire after plasma irradiation during cleaning of the bonding tool. Residual energy in the wire after plasma irradiation, if any, would be added unnecessarily to energy applied for ball forming during the subsequent bonding operation. The excessively added energy would result in unexpectedly large balls. Bonding the too large balls onto pads would result in that deformed balls bonded at the bonding positions may have an excessively large diameter and/or balls after bonding at the bonding positions may have an increased thickness, thus suffering from the above-described problems.

Hence, the present invention is directed to:

(1) a bonding apparatus configured to allow a bonding tool to clean, the apparatus including a discharge device for forming a free-air ball at a tip of a wire, a bonding tool for bonding the free-air ball formed at the tip of the wire to a first bonding position, a plasma irradiation device for performing plasma irradiation to clean the bonding tool, and a controller for controlling the discharge device, the bonding tool, and the plasma irradiation device.

The controller is configured to perform a wire bonding process (A) and a cleaning process (B). The wire bonding process (A) includes:

(a) a ball forming step of forming the free-air ball at the tip of the wire extending out from a tip of the bonding tool;

(b) a first bonding step of bonding the free-air ball formed at the tip of the wire extending out from the tip of the bonding tool to the first bonding position with the bonding tool to form a deformed ball;

(c) a wire looping step of looping the wire toward a second bonding position along a predetermined trajectory of the bonding tool while paying out the wire from the tip of the bonding tool;

(d) a second bonding step of bonding the wire extending out from the tip of the bonding tool to the second bonding position; and

(e) a wire cutting step of raising the bonding tool while paying out the wire from the tip of the bonding tool and, after reaching a predetermined height, closing a clamper to cut the wire from the second bonding position such that the wire extends out from the tip of the bonding tool.

The cleaning process (B) includes (f) a bonding tool cleaning step of cleaning the bonding tool through plasma irradiation.

The controller is also arranged to perform the cleaning process (B) after performing the wire bonding process (A) predetermined times, in which the energy of the plasma irradiation applied in the bonding tool cleaning step (f) of the cleaning process (B) is prohibited from reaching the free-air ball formed in the ball forming step (a) of the wire bonding process (A).

The bonding apparatus according to the present invention can include the following additional aspects.

(2) The controller is arranged, in the wire bonding process (A), to perform the ball forming step (a), the first bonding step (b), the wire looping step (c), the second bonding step (d), and the wire cutting step (e) in this order and, in the cleaning process (B), to perform the bonding tool cleaning step (f), followed by the ball forming step (a) as a part of the cleaning process (B), and thereafter a dummy bonding step (g) of bonding the free-air ball formed at the tip of the wire to a dummy bonding position.

(3) The controller is arranged to perform the dummy bonding step (g), followed by the wire cutting step (e) as a part of the cleaning process (B), and subsequently the ball forming step (a) of the next wire bonding process (A).

(4) The dummy bonding position is a positioning pattern.

(5) The controller is arranged, in the wire bonding process (A), to perform the ball forming step (a), the first bonding step (b), the wire looping step (c), the second bonding step (d), and the wire cutting step (e) in this order and, in the cleaning process (B), to perform the ball forming step (a) of the next wire bonding process (A) and thereafter the bonding tool cleaning step (f).

(6) After the bonding tool cleaning step (f), the next first bonding step (b) is performed at least after a prohibition period during which the energy of the plasma irradiation attenuates.

(7) The controller is arranged, in the wire bonding process (A), to perform the ball forming step (a), the first bonding step (b), the wire looping step (c), the second bonding step (d), and the wire cutting step (e) in this order and, in the cleaning process (B), to perform the bonding tool cleaning step (f) and thereafter, at least for a prohibition period during which the energy of the plasma irradiation attenuates, to prohibit the ball forming step (a) of the next wire bonding process (A).

(8) The prohibition period is a period after the plasma irradiation during which the increase in the diameter of the free-air ball by the energy of the plasma irradiation becomes substantially unobservable.

(9) The controller is arranged to perform the bonding tool cleaning step (f) after performing the wire bonding process (A) predetermined times.

(10) The present invention is also directed to a bonding tool cleaning method including a wire bonding process (A) and a cleaning process (B).

The wire bonding process (A) includes:

(a) a ball forming step of forming a free-air ball at a tip of a wire extending out from a tip of a bonding tool;

(b) a first bonding step, after the ball forming step, of bonding the free-air ball formed at the tip of the wire extending out from the tip of the bonding tool to a first bonding position with the bonding tool to form a deformed ball;

(c) a wire looping step, after the first bonding step, of looping the wire toward a second bonding position along a predetermined trajectory of the bonding tool while paying out the wire from the tip of the bonding tool;

(d) a second bonding step, after the wire looping step, of bonding the wire extending out from the tip of the bonding tool to the second bonding position; and

(e) a wire cutting step, after the second bonding step, of raising the bonding tool while paying out the wire from the tip of the bonding tool and, after reaching a predetermined height, closing a clamper to cut the wire from the second bonding position such that the wire extends out from the tip of the bonding tool.

The cleaning process (B) includes (f) a bonding tool cleaning step of cleaning the bonding tool through plasma irradiation after performing the wire bonding process (A) predetermined times.

The energy of the plasma irradiation applied in the bonding tool cleaning step (f) of the cleaning process (B) is prohibited from reaching the free-air ball formed in the ball forming step (a) of the wire bonding process (A).

The additional aspects (2) to (9) of the bonding apparatus according to the present invention are also applicable to the bonding tool cleaning method according to the present invention.

### Advantages

In accordance with the present invention, the residual energy in the bonding tool is prohibited from having an impact on the free-air ball formed in the wire, whereby the increase in the diameter of the deformed ball bonded at the bonding position can be suppressed to prevent shorting between adjacent pads and reduction in the bonding strength.

### BRIEF DESCRIPTION OF THE DRAWINGS

FIG. 1 is a configuration diagram of a semiconductor manufacturing apparatus (bonding apparatus) according to an embodiment.

FIG. 2A is an enlarged cross-sectional view of a capillary according to the embodiment.

FIG. 2B is an enlarged cross-sectional view of a plasma torch according to the embodiment.

FIG. 3A is a first enlarged cross-sectional view illustrating a ball forming step (a) according to the embodiment.

FIG. 3B is a second enlarged cross-sectional view illustrating the ball forming step (a) according to the embodiment.

FIG. 3C is a first enlarged cross-sectional view illustrating a first (ball) bonding step (b) to a first bonding position.

FIG. 3D is a second enlarged cross-sectional view illustrating the first bonding step (b).

FIG. 3E is a third enlarged cross-sectional view illustrating the first bonding step (b).

FIG. 4A is a first enlarged schematic cross-sectional view illustrating a wire looping step (c) of forming a wire loop toward a second bonding position according to the embodiment.

FIG. 4B is a second enlarged schematic cross-sectional view illustrating the wire looping step (c).

FIG. 4C is a third enlarged schematic cross-sectional view illustrating the wire looping step (c).

FIG. 4D is an enlarged schematic cross-sectional view illustrating a second (stitch) bonding step (d) to the second bonding position.

FIG. 4E is an enlarged schematic cross-sectional view illustrating a wire cutting step (e) of cutting the wire from the second bonding position.

FIG. 5A is a first cross-sectional view illustrating a bonding tool cleaning step (f) according to the embodiment.

FIG. 5B is a second cross-sectional view illustrating the bonding tool cleaning step (f) according to the embodiment.

FIG. 6 illustrates the temporal change characteristics of the energy of plasma irradiation and the change in the diameter of a deformed ball bonded at a bonding position when the ball is formed at various time points.

FIG. 7 is a partially enlarged plan view of a semiconductor die immediately before a dummy bonding step (g).

FIG. 8 is a partially enlarged plan view of the semiconductor die during the dummy bonding step (g).

FIG. 9 is a partially enlarged plan view of the semiconductor die after the dummy bonding step (g).

FIG. 10 is a flow chart illustrating a bonding tool cleaning method according to a first embodiment.

FIG. 11 is a flow chart illustrating a bonding tool cleaning method according to a second embodiment.

FIG. 12A is an enlarged cross-sectional view illustrating a ball forming step (a) according to the second embodiment.

FIG. 12B is an enlarged cross-sectional view illustrating a bonding tool cleaning step (f) according to the second embodiment.

FIG. 13 is a flow chart illustrating a bonding tool cleaning method according to a third embodiment.

### DETAILED DESCRIPTION OF THE INVENTION

Embodiments of the present invention will hereinafter be described. In the following description of the drawings, identical or similar components are designated by the same or similar reference symbols. It is noted that the drawings are illustrative only and the dimensions and geometries are schematic only, and the technical scope of the present invention should not be understood as being limited to the embodiments.

### DEFINITIONS

Terms used herein are defined as follows.

“Bonding tool”: a device used to implement a wire bonding method, with no limitation to the structure. Bonding tool is a structure, to which foreign matters can adhere at least in a bonding process, to be cleaned through plasma irradiation, including a capillary used in nail head bonding and a wedge tool used in wedge bonding. A capillary is exemplified in the embodiments, but not limited thereto as long as it is necessary to remove foreign matters.

“Cleaning”: plasma gas (hereinafter abbreviated to “plasma”) impact for removing foreign matters.

“Foreign matters”: substances adhering to the bonding tool in a bonding process, mainly including organic matters evaporated by heating from a lead frame, a substrate, and/or a wire.

“Bonding target surface”: a target surface to bond a wire thereon, including a pad formed on a semiconductor die or a substrate and a lead frame.

“Ball”: a portion formed by supplying energy to a tip of a wire to melt the wire metal, having an approximately spherical shape. The “diameter” of the “ball” means average diameter.

“Bonding”: connecting a wire and a bonding target surface in a metallic-bondable manner, including electrical connection by, for example, crimping, welding, or a combination thereof.

### EMBODIMENT

A preferred embodiment of the present invention will now be described in line with the following flow.

### 1. Configuration of a Bonding Apparatus According to the Embodiment

### (1) Overall Configuration

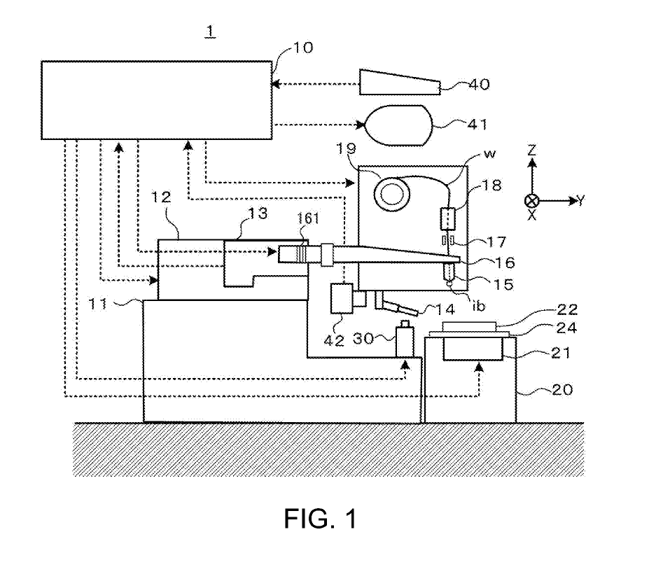

FIG. 1 is a configuration diagram of the bonding apparatus according to the embodiment.

As shown in FIG. 1, the bonding apparatus 1 according to the embodiment includes a controller 10, a base 11, an XY table 12, a bonding head 13, a torch electrode 14, a capillary 15, a bonding arm 16, a wire clamper 17, a wire tensioner 18, a rotary spool 19, a feeder 20, a heater 21, a plasma irradiation device 30, an operation unit 40, a display 41, and a camera 42.

In the following embodiments, a plane parallel to a bonding target semiconductor die or lead frame is defined as XY plane and the direction perpendicular to the XY plane is defined as Z direction. The tip position of the capillary 15 is identified with a spatial coordinate (X, Y, Z) represented by an X coordinate, a Y coordinate, and a Z coordinate.

The base 11 has the XY table 12 placed slidably thereon. The XY table 12 is a moving device that can move the capillary 15 to a predetermined position on the XY plane based on a drive signal from the controller 10.

The bonding head 13 is a moving device that holds the bonding arm 16 movably in the Z direction based on a drive signal from the controller 10. The bonding head 13 has a lightweight low center-of-gravity structure and can suppress movement of the capillary 15 due to an inertia force generated with the movement of the XY table 12.

The bonding arm 16 is a rod-shaped member including a base end portion, a flange portion, a horn portion, and a tip portion from the base to the tip thereof. The base end portion is provided with an ultrasonic transducer 161 arranged to vibrate in response to a drive signal from the controller 10. The flange portion is attached to the bonding head 13 in a resonance manner at a position that serves as a node of ultrasonic vibration. The horn portion is an arm extending longer than the diameter of the base end portion, having a structure for amplifying and transmitting the amplitude of vibration by the ultrasonic transducer 161 to the tip portion. The tip portion is a mounting portion for replaceably holding the capillary 15. The bonding arm 16 has, as a whole, a resonance structure that resonates with vibration by the ultrasonic transducer 161, in which the ultrasonic transducer 161 and the flange are positioned at nodes of resonance vibration, while the capillary 15 is positioned at an anti-node of vibration. With these arrangements, the bonding arm 16 serves as a transducer for converting an electrical drive signal into a mechanical vibration.

The capillary 15 is a part of a bonding tool to be cleaned according to the embodiment. An insertion hole is provided in the capillary 15, through which a wire “w” for bonding can be inserted and paid out. The capillary 15 is attached replaceably to the bonding arm 16 with a spring force or the like.

The wire clamper 17 has an electromagnetic structure to open and close based on a control signal from the controller 10, whereby the wire “w” can be held and released at predetermined timing.

The wire tensioner 18 can insert the wire “w” therethrough and freely change a sliding force for the wire “w” based on a control signal from the controller 10 to apply a moderate tensile force to the wire “w” during bonding.

The rotary spool 19 replaceably holds a reel with the wire “w” wound therearound and is arranged to pay out the wire “w” according to the tensile force applied by the wire tensioner 18. It is noted that the material of the wire “w” is selected from those having high machinability and low electrical resistance. Gold (Au), aluminum (Al), copper (Cu), or the like is generally used.

The torch electrode 14 is connected to a high-voltage power source not shown through a discharge stabilization resistor not shown and is arranged to generate spark (discharge) based on a control signal from the controller 10 and, with the heat of the spark, form a ball at the tip of the wire “w” paid out from the tip of the capillary 15. The position of the torch electrode 14 is fixed and, upon discharging, the capillary 15 comes close to the torch electrode 14 at a predetermined distance to generate moderate spark between the tip of the wire “w” and the torch electrode 14.

The feeder 20 is a machining table with a machining surface to place a bonding target semiconductor die 22 and lead frame 24 thereon. The heater 21 is provided under the machining surface of the feeder 20 to heat the semiconductor die 22 and the lead frame 24 to a temperature suitable for bonding.

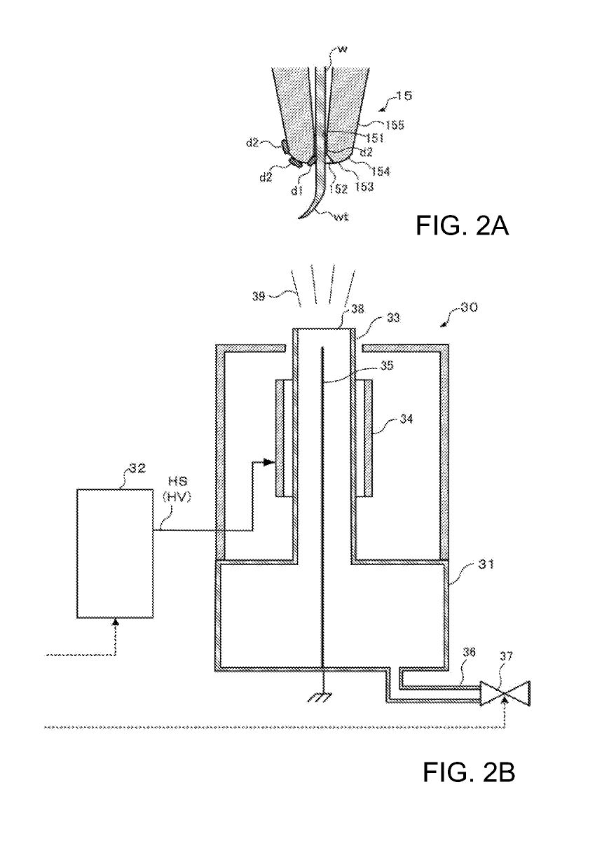

The plasma irradiation device 30 is provided in the vicinity of the feeder 20 and is arranged to perform plasma irradiation based on a control signal from the controller 10, as will be described in detail with reference to FIG. 2.

The operation unit 40 includes input means such as a trackball, a joystick, and a touch panel that serve as an input device for outputting operations by an operator to the controller 10. The camera 42 is arranged to take an image of the semiconductor die 22 and the lead frame 24 placed on the machining surface of the feeder 20. The display 41 is arranged to display an image taken by the camera 42 at a predetermined magnification visible to the operator. The operator can operate the operation unit 40 and set the trajectory of the capillary 15 while observing a pad 23 on the semiconductor die 22 and the lead frame 24 displayed on the display 41.

The controller 10 is arranged to output various control signals for controlling the bonding apparatus 1 based on a predetermined software program. Specifically, the controller 10 performs the following controls as a non-limiting example.

(1) Identify the spatial position (X, Y, Z) of the tip of the capillary 15 based on a detection signal from a positional detection sensor not shown and output to the XY table 12 and the bonding head 13 a drive signal for moving the capillary 15 to a spatial position defined by the program.

(2) Output to the ultrasonic transducer 161 of the bonding arm 16 a control signal for generating ultrasonic vibration during bonding to a bonding point.

(3) Output a control signal for controlling the opening and closing operation of the wire clamper 17 such that the wire “w” is paid out as defined by the program. Specifically, open the wire clamper 17 to pay out the wire “w”, while close the wire clamper 17 to form a folding point in the wire “w” or to cut the wire “w”.

(4) Output a control signal for discharging at the torch electrode 14 when forming a ball at the tip of the wire “w”.

(5) Output an image from the camera 42 on the display 41.

(6) Identify the spatial coordinate of a bonding point, a folding point, etc. based on operations on the operation unit 40.

(7) Output a control signal to the plasma irradiation device 30 during plasma irradiation.

It is noted that the configuration of the bonding apparatus 1 is illustrative only and should not be limited thereto. For example, the feeder 20 or both the bonding apparatus 1 and the feeder 20 each can be provided with a moving device for X-, Y-, and Z-direction movement.

### (2) Specific Configuration for Cleaning

FIG. 2A is an enlarged cross-sectional view of the capillary 15 in an arrangement for plasma irradiation. FIG. 2B is an enlarged cross-sectional view of the plasma irradiation device 30. As shown in FIG. 2B, the plasma irradiation device 30 includes a gas chamber 31, a high-frequency signal generator 32, a plasma torch 33, a load electrode 34, a grounding electrode 35, a gas pipe 36, and a shutoff valve 37.

The gas chamber 31 is in communication with the plasma torch 33 and serves as a gas-filled chamber for supplying gas for plasma generation to the plasma torch 33. The gas pipe 36 is a supply passage for supplying gas for plasma generation therethrough from a gas supply source not shown to the gas chamber 31. The shutoff valve 37 is an electromagnetic valve arranged to close and open based on a control signal from the controller 10, whereby gas for plasma generation flowing through the gas pipe 36 can be shut off and allowed to flow.

It is noted that the gas for plasma generation can be Ar, N₂, a mixture thereof with a trace of H₂ or O₂ gas, or CDA (Clean Dry Air).

The high-frequency signal generator 32 includes, for example, a high-frequency power source, a forward wave/reflective wave detector, a high-voltage generator, and a superposition coil, though not shown. Based on a control signal from the controller 10, the high-frequency signal generator 32 generates a high voltage HV for igniting gas for plasma generation and a high-frequency signal HS for generating and maintaining plasma.

The plasma torch 33 is a hollow structure composed of an insulating material corrosion-resistant to plasma and heat-resistant to the high temperature of plasma, being formed in a cylindrical shape as an example. The load electrode 34 is provided in a manner surrounding the outer peripheral surface of the plasma torch 33. The load electrode 34 is arranged to be provided with a high-frequency signal HS (high voltage HV) from the high-frequency signal generator 32. The grounding electrode 35 is provided within the hollow of the plasma torch 33 in a longitudinally extending manner. The grounding electrode 35 is paired with the load electrode 34 and electrically grounded via a wall surface of the gas chamber 31.

In addition, the high-frequency signal generator 32 and the load electrode 34 are connected through a coaxial cable and a matching device is also provided for adjusting the impedance as a system of the plasma irradiation device, though not shown. The matching device is designed such that the load impedance when plasma is generated stably equals a predetermined characteristic impedance.

An operation of the plasma irradiation device 30 will now be described.

When the shutoff valve 37 is opened based on a control signal from the controller 10 shown in FIG. 1, pressurized gas for plasma generation flows through the gas chamber 31 into the plasma torch 33 shown in FIG. 2 to flow around the grounding electrode 35 at high speed. After that, when a plasma ignition instruction is output to the high-frequency signal generator 32 based on a control signal from the controller 10, a predetermined high-frequency signal HS and a predetermined high voltage HV are output in a superimposed manner to the load electrode 34. In the case of using argon, which is inert, for example, as the gas for plasma generation, when the high-frequency signal HS with the high voltage HV superimposed thereon is provided, a high-frequency electric field is generated between the load electrode 34 and the grounding electrode 35 under the argon atmosphere, whereby argon atoms are excited and argon electrons are accelerated to collide with surrounding argon gas particles (molecules) and thereby push out further electrons. The electrons are accelerated in the electric field to further collide with other gas particles, so that the number of electrons increases acceleratedly and argon atoms are ionized into Ar⁺ (argon ions), e⁻ (electrons), and Ar* (argon radicals), and thus plasma is generated. When the plasma is generated, the superimposition of the high voltage HV is stopped. The matching device performs known impedance matching processing to provide impedance matching in a view from the high-frequency signal generator 32. Argon gas is excited or ionized around the grounding electrode 35 and then delivered as ionized plasma 39 through an opening 38 of the plasma torch 33.

Referring now to FIG. 2A, a cross-sectional view of a tip portion of the capillary 15 with the wire “w” inserted therethrough is shown. As shown in FIG. 2A, the tip portion of the capillary 15 includes a straight hole 151, a chamfer portion 152, a face portion 153, and an outer-radius portion 154. The straight hole 151 defines an inner wall through which the wire “w” is inserted. The face portion 153 is a tip face of the capillary 15 provided at a small angle with respect to a bonding target surface. The chamfer portion 152 provides connection between the straight hole 151 and the face portion 153, formed in a tapered shape from the straight hole 151 to the face portion 153. The outer-radius portion 154 provides connection between the face portion 153 and the outer peripheral surface 155 of the capillary 15. A wire tail “wt” is formed at the tip of the wire “w” inserted through the straight hole 151.

As shown in FIG. 2A, metallic foreign matters d1 adhere around the corner between the chamfer portion 152 and the face portion 153 of the capillary 15 after repeated bonding operations. Organic foreign matters d2 adhere to the outer peripheral surface 155. The organic foreign matters d2 are generated to adhere to the surface of the capillary 15 as a result of evaporation or entrainment, by the heat during bonding, of organic matters applied on a lead frame, substrate, and/or wire surface.

The plasma 39, when applied to the tip portion of the capillary 15 through the opening 38 of the plasma torch 33 as shown in FIG. 2B, collides with and removes the organic foreign matters d2.

In order that the organic foreign matters d2 can be removed easily, it is preferable to provide a control signal from the controller 10 to the ultrasonic transducer 161 of the bonding arm 16 during plasma irradiation to apply ultrasonic vibration to the capillary 15. The ultrasonic vibration causes the capillary 15 to oscillate and thereby the wire “w” to have a small movement. The small movement causes the plasma 39 to be applied thoroughly to the straight hole 151, the chamfer portion 152, the face portion 153, the outer-radius portion 154, and the outer peripheral surface 155, whereby the foreign matters can be removed effectively. The small movement also allows the foreign matters to be separated easily and thus removed effectively.

It is noted that the plasma irradiation device 30 is illustrative only and can employ various other structures. An atmospheric-pressure plasma device-based structure can be employed if the bonding environment is under atmospheric pressure, while a vacuum plasma device-based structure can be employed if under vacuum atmosphere. Also, the specific structure for plasma generation is not limited to the embodiment above. For example, multiple plasma torches can be provided. Further, there is no limitation to plasma as long as foreign matters can be removed effectively. For example, oxygen-based radical irradiation or hydrogen-based plasma irradiation can be applied.

If it is necessary to discharge removed foreign matters with no entrainment over the bonding areas, it is preferable to provide an exhaust mechanism in the vicinity of the plasma irradiation device 30.

### (3) Basic Operation of the Apparatus

An operation of the bonding apparatus 1 according to the embodiment will now be described.

What should be done first is to record the trajectory of the tip of the capillary 15 that defines the geometry (e.g. starting point, folding point, and ending point) of the wire “w” as set points in the controller 10. Bonding targets such as the semiconductor die 22 and the lead frame 24 are placed on the feeder 20. The semiconductor die 22 is bonded with adhesive agent to an island portion of the lead frame 24. The starting point is the pad 23 on the semiconductor die 22 and the ending point is the lead frame 24, for example. Set points at which the direction of movement of the capillary 15 changes are recorded with the wire “w” being restrained to form a loop including folding points.

The operator operates the operation unit 40 while observing on the display 41 an image taken with the camera 42 to record the spatial coordinate of the set points. Specifically, the operator records the X and Y coordinates of a desired point by, for example, inputting the coordinate information of the point using the operation unit 40 or positioning a marker displayed on the display 41 to the point and inputting the coordinate information. The operator also records the Z coordinate by numerically inputting the displacement in the Z direction from a reference surface (e.g. surface of the lead frame 24) using the operation unit 40.

It is necessary to record the spatial coordinate of the set points for all wires “w” to be bonded before starting a bonding operation. The controller 10 moves the capillary 15 relative to the semiconductor die 22 and the lead frame 24 in the order of the recorded set points along the recorded trajectory while repeating release and hold by the wire clamper 17 to perform a bonding operation. This will hereinafter be described in detail.

### 2. Description of a Bonding Method According to the Embodiment

### (1) Description of Basic Steps

The bonding method according to the embodiment includes (a) a ball forming step, (b) a first (ball) bonding step to a first bonding position, (c) a wire looping step of forming a wire loop toward a second bonding position, (d) a second (stitch) bonding step to the second bonding position, (e) a wire cutting step of cutting the wire from the second bonding position, and (f) a bonding tool cleaning step. The ball forming step (a), the first bonding step (b), the wire looping step (c), the second bonding step (d), and the wire cutting step (e) constitute a typical wire bonding process (A) for bonding one wire “w”. These steps (a) to (e) are repeated to bond multiple wires “w”.

In contrast, the bonding tool cleaning step (f) is only required to perform once after repeating the ball forming step (a) to the wire cutting step (e) included in the typical wire bonding process (A) certain times (e.g. 0.5 to 1 million times). The frequency of the bonding tool cleaning step (f) can depend on the contamination conditions such as the amount of accumulation of foreign matters.

### (a) Ball Forming Step

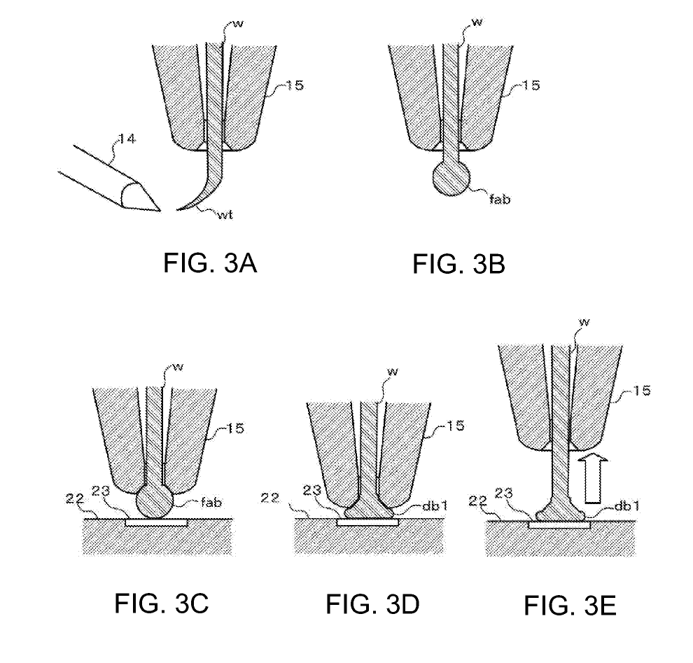

FIGS. 3A and 3B are enlarged cross-sectional views illustrating the ball forming step according to the embodiment, taken along the axis of the capillary 15.

The ball forming step is a step of forming a ball at the tip of the wire “w”. As shown in FIG. 3A, when the previous wire bonding process (A) (steps (a) to (e)) is completed, a wire tail “wt” is formed at the tip of the wire “w” extending out from the tip portion of the capillary 15. The controller 10 provides a drive signal to the XY table 12 and the bonding head 13 to position the wire tail “wt” at the tip of the capillary 15 at a predetermined distance from the fixed torch electrode 14. After that, the controller 10 outputs a control signal to generate spark between the torch electrode 14 and the wire tail “wt”. Since all metallic members including the wire “w” are fixed to the ground potential, applying a predetermined high voltage to the torch electrode 14 causes discharge between the torch electrode 14 and the wire tail “wt”.

As shown in FIG. 3B, when the spark is generated, the heat melts the metal member of the wire tail “wt” and a free-air ball (hereinafter abbreviated to “ball”) “fab” is formed due to surface tension. The diameter of the ball “fab” depends on the distance between the torch electrode 14 and the wire tail “wt” when the spark is generated and/or the amount of applied energy such as the discharge current and time of the spark. The distance between the torch electrode 14 and the wire tail “wt” and the discharge current and time are adjusted such that the ball “fab” is formed to have a volume to result in a deformed ball “db1” with an appropriate diameter after bonding to the first bonding position using the capillary 15.

### (b) First (Ball) Bonding Step

FIGS. 3C to 3E are enlarged cross-sectional views illustrating the first (ball) bonding step (b) according to the embodiment, taken along the axis of the capillary 15.

The first (ball) bonding step to the first bonding position is a step of bonding the ball “fab” formed at the tip of the wire “w” to the bonding target surface, specifically including a step of forming a deformed ball “db1” at the first bonding position (FIGS. 3C to 3E).

In the step of forming the deformed ball “db1” at the first bonding position, as shown in FIG. 3C, the controller 10 first provides a drive signal to the XY table 12 and the bonding head 13 to move the spatial position of the capillary 15 to a preset starting point. The starting point is, for example, the pad 23 formed on the semiconductor die 22. The controller 10 then provides a drive signal to the bonding head 13 and, performing position search, lowers the capillary 15 with the ball “fab” formed thereon toward the center of the pad 23 on the semiconductor die 22.

As shown in FIG. 3D, when the ball “fab” comes into contact with the pad 23, the front edge of the ball “fab” starts to be deformed due to the impact from the predetermined lowering speed and further deformed due to the bonding force applied to the capillary 15. At the same time, the controller 10 provides a control signal to the bonding arm 16 to cause the ultrasonic transducer 161 to generate ultrasonic vibration to be applied to the ball “fab” through the bonding arm 16 and the capillary 15. In this case, since the pad 23 on the semiconductor die 22 is heated appropriately by the heater 21, the ball “fab” is bonded onto the pad 23 by the interaction of the bonding force applied to the ball “fab”, the ultrasonic vibration, and the heat applied by the heater 21. This results in the deformed ball “db1” as a starting point. The deformed ball “db1” at the first bonding position is deformed correspondingly to the shape of the tip portion (chamfer portion 152, face portion 153, and outer-radius portion 154) of the capillary 15 to be bonded with a diameter greater than that of the ball “fab”.

As shown in FIG. 3E, after forming the deformed ball “db1” at the first bonding position, the controller 10 provides a drive signal to the bonding head 13 to raise the spatial position of the tip of the capillary 15.

### (c) Wire Looping Step

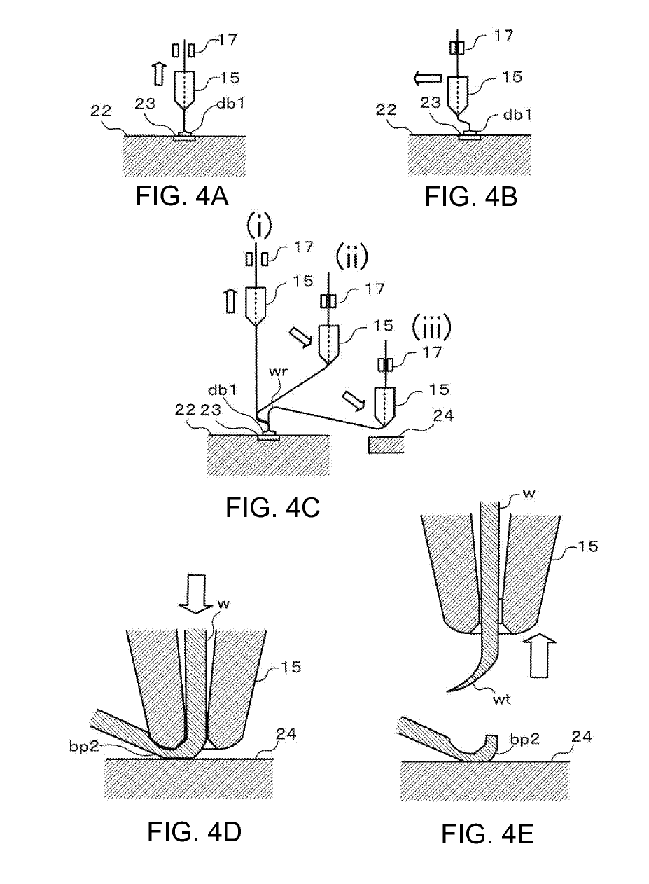

FIGS. 4A to 4C schematically illustrates the wire looping step (c) according to the embodiment about how the capillary 15 moves with respect to the pad 23.

In the wire looping step (c), as shown in FIG. 4A, the capillary 15 is first raised to a preset height, following which, as shown in FIG. 4B, the controller 10 provides a control signal to the wire clamper 17 to hold the wire “w” and provides a drive signal to the XY table 12 and the bonding head 13 to perform a reverse operation in which the capillary 15 is once moved in the direction against the second bonding position. Next, as shown in FIG. 4C (i), the controller 10 opens the wire clamper 17 and raises the capillary 15 to pay out the wire “w” by a length required for the wire bonding.

After that, as shown in FIG. 4C (ii), the controller 10 again closes the wire clamper 17 and moves the capillary 15 toward the second bonding position on the lead frame 24. This movement causes the wire “w” to be formed in a loop including a folding point “wr”.

When the loop is formed, as shown in FIG. 4C (iii), the controller 10 provides a drive signal to the XY table 12 and the bonding head 13 to move the spatial position of the capillary 15 toward a preset ending point. The ending point is, for example, the second bonding position set on the lead frame 24. The controller 10 provides a drive signal to the bonding head 13 and, performing position search, lowers the capillary 15 to bring the wire “w” into contact with the second bonding position on the lead frame 24.

It is noted that after forming the folding point “wr”, the capillary 15 can be moved along a predetermined trajectory other than that shown in FIG. 4C to cause the wire “w” to be formed in a second wire loop having a different geometry.

### (d) Second (Stitch) Bonding Step

FIG. 4D is an enlarged cross-sectional view illustrating the second (stitch) bonding step according to the embodiment, taken along the axis of the capillary 15.

As shown in FIG. 4D, when the wire “w” held in the capillary 15 comes into contact with the lead frame 24, the portion of the wire “w” between the tip portion (chamfer portion 152, face portion 153, and outer-radius portion 154) of the capillary 15 and the lead frame 24 is deformed due to the impact from the lowering speed of the capillary 15 and the bonding force applied to the capillary 15. At the same time, the controller 10 provides a control signal to the bonding arm 16 to cause the ultrasonic transducer 161 to generate ultrasonic vibration to be applied to the wire “w” through the bonding arm 16 and the capillary 15. Since the lead frame 24 is heated appropriately by the heater 21, the portion of the wire “w” in contact with the lead frame 24 is bonded onto the lead frame 24 by the interaction of the bonding force applied to the wire “w”, the ultrasonic vibration, and the heat applied by the heater 21. In this case, the wire “w”, which is applied with the bonding force by the capillary 15, is bent along the shape of the chamfer portion 152 in the close vicinity of the bonding position where the wire “w” is bonded.

### (e) Wire Cutting Step

FIG. 4E is an enlarged cross-sectional view illustrating the wire cutting step according to the embodiment, taken along the axis of the capillary 15.

As shown in FIG. 4E, when the wire “w” is bonded onto the lead frame 24, the controller 10 provides a control signal to the wire clamper 17 to hold the wire “w” and then provides a drive signal to the bonding head 13 to raise the capillary 15. The wire “w”, when pulled forcibly with being bonded onto the lead frame 24 and thus applied with a tensile force, undergoes a fracture at the thinned portion bent along the shape of the chamfer portion 152 (tail cut). The fractured portion bonded to the lead frame 24 serves as a second bonding position “bp2”. Since the wire “w” thinned along the shape of the chamfer portion 152 is thus drawn out to be fractured, the tip of the wire “w”, which is separated from the second bonding position “bp2”, has a tapered shape to be a wire tail “wt”. The stitch bonding step to the second bonding position is thus completed.

The one wire “w” is thus bonded completely in the wire bonding process (A) constituted by the first (ball) bonding step (b) to the first bonding position, the wire looping step (c), the second (stitch) bonding step (d) to the second bonding position, and the wire cutting step (e) of cutting the wire from the second bonding position. The ball forming step (a) to the wire cutting step (e) are then repeated to perform wire bonding repeatedly between pads 23 formed on the semiconductor die 22 and the lead frame 24.

### (f) Bonding Tool Cleaning Step

The bonding tool cleaning step is a step of cleaning the capillary 15 with the plasma irradiation device 30. As illustrated in FIG. 2A, repeating the wire bonding process (A) causes metallic foreign matters d1 and organic foreign matters d2 to adhere to the tip portion of the capillary 15. The following bonding tool cleaning step (f) is hence required to perform once after repeating the wire bonding process (A) certain times.

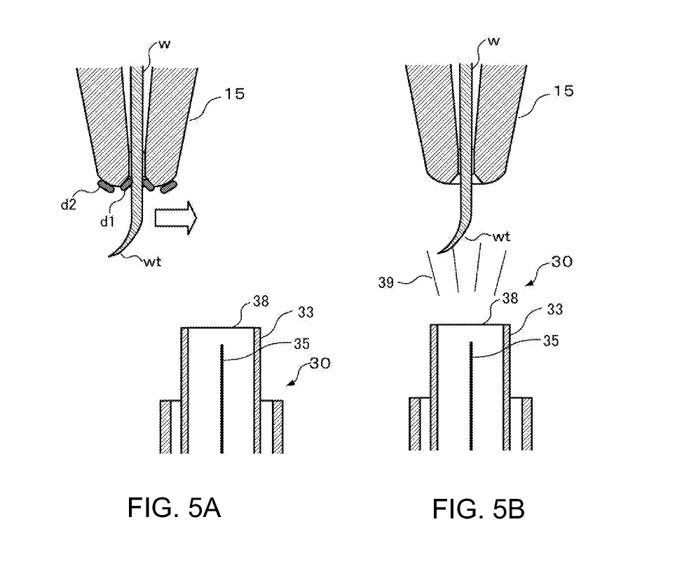

FIGS. 5A and 5B are enlarged cross-sectional views illustrating the cleaning step according to the embodiment, taken along the axes of the capillary 15 and the plasma torch 33.

When it comes time to perform the bonding tool cleaning step (f), the controller 10 provides a drive signal to the XY table 12 and the bonding head 13 to move the spatial position of the capillary 15 toward a preset cleaning position as shown in FIG. 5A. The cleaning position is a position where the plasma irradiation device 30 can be used for cleaning, for example, directly above the opening 38 of the plasma torch 33, where jet flow of the plasma 39 collides at a strength at which the organic foreign matters d2 can be removed.

When the tip portion of the capillary 15 comes to the cleaning position, the controller 10 provides a control signal to the shutoff valve 37 to cause argon gas as pressurized inert gas for plasma generation to flow through the gas chamber 31 into the plasma torch 33 as shown in FIG. 5B. The argon gas flows around the grounding electrode 35 at high speed. After that, the controller 10 provides a control signal to the high-frequency signal generator 32. The high-frequency signal generator 32 outputs a high-frequency signal HS with a high voltage HV superimposed thereon between the grounding electrode 35 and the load electrode 34. When the high-frequency signal HS with the high voltage HV superimposed thereon is provided, a high-frequency electric field is generated between the load electrode 34 and the grounding electrode 35, whereby argon atoms are excited and argon electrons are accelerated to collide with surrounding argon gas particles (molecules) and thereby push out further electrons. The electrons are accelerated in the electric field to further collide with other gas particles, so that the number of electrons increases acceleratedly and argon atoms are ionized into Ar′ (argon ions), e (electrons), and Ar* (argon radicals), and thus plasma is generated. Argon gas particles partially ionized by the ionization or excitation effect of the generated plasma are delivered as plasma 39 through the opening 38 of the plasma torch 33 toward the tip portion of the capillary 15. The plasma 39, when applied to the tip portion of the capillary 15, collides with and removes the organic foreign matters d2.

Also, the controller 10 preferably provides a control signal to the ultrasonic transducer 161 of the bonding arm 16 to apply ultrasonic vibration to the capillary 15. The ultrasonic vibration causes the capillary 15 to oscillate and thereby the wire “w” to have a small movement, which allows the plasma 39 to collide with all surfaces in the tip portion of the capillary 15 and thereby the foreign matters to be removed effectively.

The plasma irradiation continues for a time period during which the organic foreign matters d2 can be removed. The average amount of foreign matters adhering to the tip portion of the capillary 15 can be estimated according to the frequency of the bonding tool cleaning step (f). The cleaning time is set enough to reliably remove foreign matters in the average amount. The longer the cleaning time, the more reliably the foreign matters can be removed, which, however, results in poor productivity. In addition, the longer the cleaning time, the more the amount of energy of the plasma irradiation is to be applied as will hereinafter be described, which increases the time until the next wire bonding process (A) can be performed and results in poorer productivity. For these reasons, the cleaning time should be determined weighing the cleaning effect and the productivity decline due to the plasma irradiation.

After the bonding tool cleaning step (f), the controller 10 restarts the wire bonding process (A) including the ball forming step (a) to the wire cutting step (e).

### (2) Understanding of the Problem

The combination of the wire bonding process (A) including the ball forming step (a) to the wire cutting step (e) and the bonding tool cleaning step (f) has conventionally been considered under the condition of only the relationship between the cleaning effect for foreign matters and the productivity as mentioned above. However, the inventors of this application have found that the energy of the plasma irradiation applied in the bonding tool cleaning step (f) can be a problem in forming the deformed ball “db1”. This will hereinafter be described.

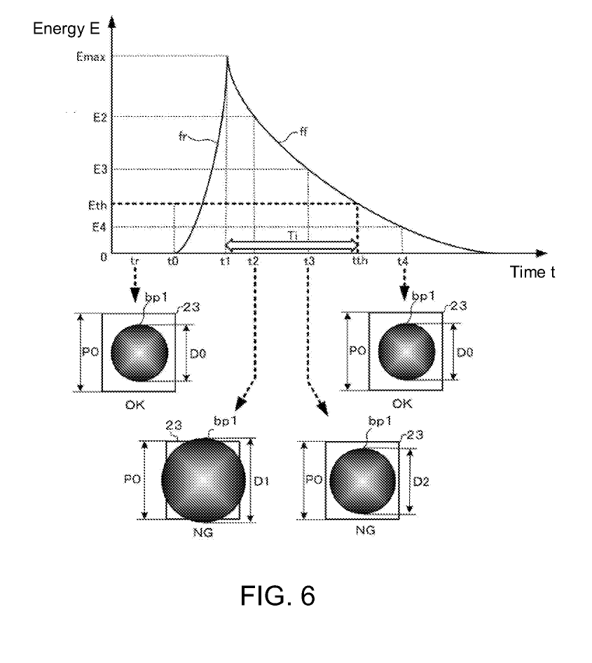

FIG. 6 illustrates the temporal change characteristics of the energy of plasma irradiation and the change in the diameter of a deformed ball “db1” bonded at a bonding position when the ball is formed at various time points. In the temporal change characteristics of the energy shown in the upper half of FIG. 6, the characteristic “fr” indicates that the energy E stored in the tip portion of the capillary 15 during the plasma irradiation increases, while the characteristic “ff” indicates that the energy E stored in the wire tail “wt” after stopping the plasma irradiation attenuates. The plan views corresponding to the respective time points shown in the lower half of FIG. 6 show a bonding surface of the deformed ball “db1” bonded and formed on the pad 23 at the first bonding position.

In the plan view corresponding to the time point “tr”, the deformed ball “db1” is obtained through the ball forming step (a) with no influence of the plasma irradiation in the bonding tool cleaning step (f). The diameter D0 of the deformed ball “db1” formed at the first bonding position with respect to the width PO of the pad 23 is adjusted and optimized from the viewpoints of the bonding strength to the pad 23 and the distance from adjacent pads 23. That is, the smaller the diameter D0 of the deformed ball “db1” at the first bonding position with respect to the width PO of the pad 23, the greater the spatial distance from adjacent bonding points and thereby the lower the risk of shorting and/or protruding from the pad 23 and also the shorter the bonding time can be. In contrast, the smaller the diameter D0 of the deformed ball “db1”, the smaller the bonding area with the pad 23 and thereby the lower the bonding strength of the deformed ball “db1” to the pad 23. The lowered bonding strength could increase the likelihood that the deformed ball “db1” formed at the first bonding position is separated and/or sheared from the pad 23 during the looping step of forming a predetermined folding point in the wire “w” or the second (stitch) bonding step to the second bonding position. In addition, the smaller the bonding area between the deformed ball “db1” formed at the first bonding position and the pad 23, the higher the contact resistance can be. Hence, in consideration of the above-described circumstances, the bonding apparatus 1 has an arrangement in which the contact impact and static bonding force by the capillary 15, the temperature of heating by the heater 21, and the frequency and amplitude of ultrasonic vibration applied to the capillary 15 are adjusted such that the diameter D0 of the deformed ball “db1” formed at the first bonding position is appropriate with respect to the pad 23.

However, since energy resulting from the plasma irradiation is stored in the tip portion of the wire (hereinafter referred to as “wire tip portion”) serving as the wire tail “wt” extending from the tip portion of the capillary 15 immediately after the cleaning step (f), the deformed ball “db1” is to be formed at the first bonding position to have a larger diameter due to the residual energy in the ball forming step (a) immediately after the bonding tool cleaning step (f).

In FIG. 6, the plasma irradiation in the bonding tool cleaning step (f) starts at the time point “t0” and ends at the time point “t1”. During the plasma irradiation, the energy E applied in the wire tip portion increases rapidly, as indicated by the characteristic “fr”, to reach the maximum value Emax at the time point “t1” when the plasma irradiation ends. After the plasma irradiation, the energy E stored in the wire tip portion attenuates as the heat transfers through air or metals as indicated by the characteristic “ff”.

However, since a substantially large amount of energy E still remains in the wire tip portion at the time point “t2”, the diameter D1 of the deformed ball “db1” formed at the first bonding position by performing the ball forming step (a) at this time point is greater than the width PO of the pad 23 and protrudes out of the pad 23. This inadequately suffers from a high risk of shorting with adjacent bonding points.

Even at the time point “t3” when a further time has elapsed, since an amount of energy enough to influence the formation of the ball “fab” still remains in the wire tip portion, the diameter D2 of the deformed ball “db1” formed at the first bonding position by performing the ball forming step (a) at this time point still inadequately misses a sufficient margin to be provided from the safety viewpoint, though can be smaller than the width PO of the pad 23.

As a further time has elapsed, the energy remaining in the wire tip portion cannot significantly influence the diameter of the deformed ball “db1” of the formed ball “fab”. The threshold value of the energy remaining in the wire tip portion at this time point is represented by Eth and the time point when the residual energy becomes Eth is represented by “tth”. After the time point “tth”, the energy E remaining in the wire tip portion is sufficiently low. For example, at the time point “t4” in FIG. 6, the diameter of the deformed ball “db1” formed at the first bonding position by performing the ball forming step (a) at this time point is D0, which is adequately adjusted as usual.

### (3) Principle of Solutions

As can be expected from the foregoing considerations, if it is possible to prohibit the formation of the deformed ball “db1” at the first bonding position on the pad 23 until the energy E remaining in the wire tip portion becomes Eth and also to prohibit the bonding, at the first bonding position, of the free-air ball “fab” formed before the energy E remaining in the wire tip portion becomes Eth, the foregoing inconveniences associated with the energy remaining in the wire tip portion can be avoided. The inventors of this application have hence defined the time period from the time point “t1” to “tth” during which the energy of the plasma irradiation attenuates after the plasma irradiation in the bonding tool cleaning step (f) as “prohibition period” and found prohibiting bonding of the ball “fab” formed during the prohibition period onto the bonding target surface as the principle of solutions for the problem. The strategy for this is not to use the ball “fab” formed during the prohibition period for bonding of the wire “w” or not to form the ball “fab” during the prohibition period, but the following three specific solutions have occurred. The prohibition period can be, in other words, a period during which the increase in the diameter of the ball “fab” by the energy of the plasma irradiation becomes substantially unobservable.

(First Solution)

The first solution can be, in the wire bonding process (A), to perform the ball forming step (a), the first (ball) bonding step (b), the wire looping step (c), the second (stitch) bonding step (d), and the wire cutting step (e) in this order and, in the cleaning process (B), to perform the bonding tool cleaning step (f), followed by the ball forming step (a), and thereafter a dummy bonding step (g) of bonding the ball “fab” formed at the tip of the wire “w” to a dummy bonding surface.

As illustrated in FIG. 6, performing the ball forming step (a) during the prohibition period during which a relatively large amount of energy E remains in the wire tip portion causes a deformed ball “db1” to be formed at the first bonding position, which is the practical problem. When considered upside down, the ball “fab” formed during the prohibition period, if discarded, cannot be bonded onto the pad 23, where the above-described manufacturing problem cannot occur. In accordance with the first solution, when the ball forming step (a) is performed during the prohibition period, the ball “fab” is bonded not onto the regular bonding target surface but onto the dummy bonding surface. Thus, in accordance with the first solution, there is no need to wait until the residual energy of the plasma generation attenuates, which cannot deteriorate the productivity. Even if the bonding tool cleaning step (f) can be inserted irregularly or regularly in the wire bonding processes (A) from the ball forming step (a) to the wire cutting step (e), the rhythm of the repetition of the steps cannot be disrupted. It is also possible to restart the regular ball forming step (a) immediately after the prohibition time has elapsed, which can improve the productivity.

### (g) Dummy Bonding Step

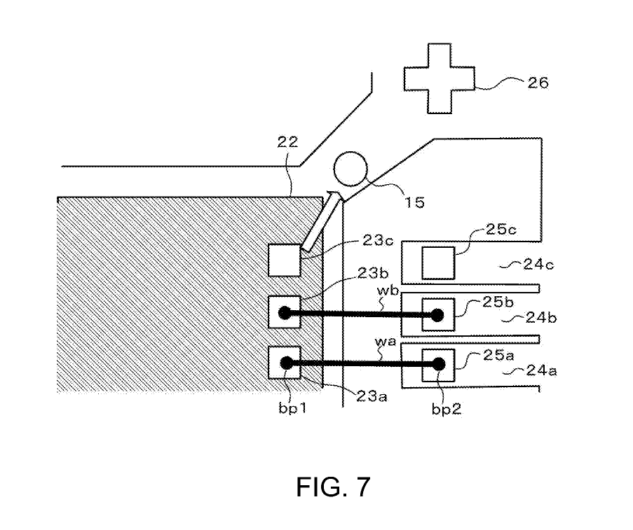

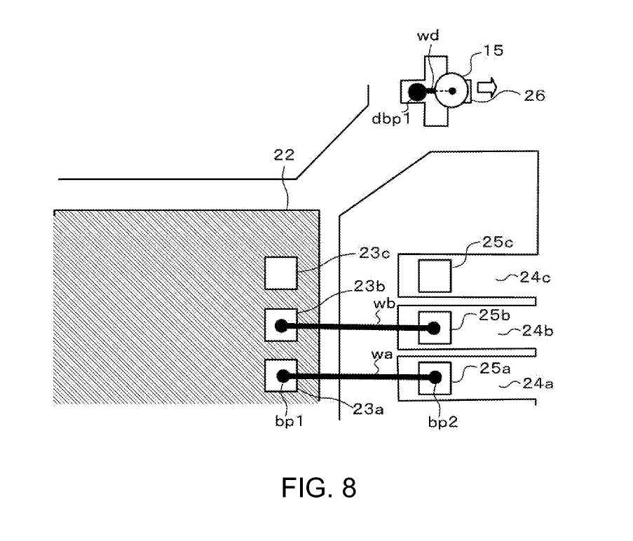

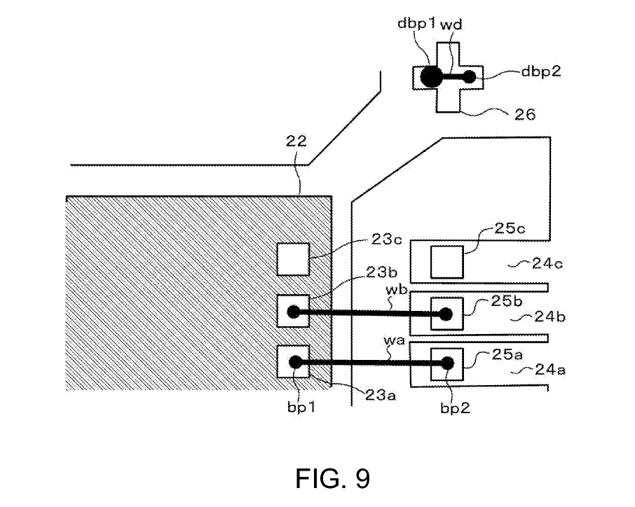

The dummy bonding step (g) will be described with reference to FIGS. 7 to 9. FIG. 7 is a partially enlarged plan view of a semiconductor die immediately before the dummy bonding step (g). FIG. 8 is a partially enlarged plan view of the semiconductor die during the dummy bonding step (g). FIG. 9 is a partially enlarged plan view of the semiconductor die after the dummy bonding step (g).

In FIGS. 7 to 9, the semiconductor die 22 is partially enlarged to be shown. Pads 23 (23a to 23c) each serving as a first bonding position are formed on the semiconductor die 22. A Lead frame 24 including a second bonding position is also shown. The lead frame 24 includes not only the second bonding position but also a positioning pattern 26 formed though not used directly for bonding. The positioning pattern 26 is prepared as a mark for positioning when performing a wire bonding operation. It is noted that the positioning pattern 26 is an area formed on the same plane as the lead frame 24, on which bonding can be performed. Hence, in the embodiment, the positioning pattern 26 is utilized as a dummy bonding surface to be used in the dummy bonding step.

At the time point of FIG. 7, the pad 23a and the lead 24a are connected through the wire “wa” and the pad 23b and the lead 24b are connected through the wire “wb” by applying the wire bonding process (A) including the ball forming step (a) to the wire cutting step (e). The bonding tool cleaning step (f) is performed after the wire “wb” is bonded. Performing the ball forming step (a) immediately after the bonding tool cleaning step (f) causes a ball “fab” having a diameter greater than usual to be formed under the influence of the residual energy of the plasma irradiation as mentioned above. The process then goes to the dummy bonding step (g).

In the dummy bonding step (g), the controller 10 provides a drive signal to the XY table 12 to move the planar position of the capillary 15 to the position of the positioning pattern 26 as shown in FIG. 7.

Next, as shown in FIG. 8, the controller 10 provides a drive signal to the bonding head 13 to lower the capillary 15 and form a dummy bonding “dbp1” on the positioning pattern 26. In this case, the ball “fab” formed at the tip of the capillary 15 has a diameter greater than usual. The dummy bonding “dbp1” formed on the positioning pattern 26 therefore has a diameter greater than that of the deformed ball “db1” bonded to the regular first bonding position (as shown correspondingly to the time points t2 and t3 in FIG. 6, for example). After that, a looping operation is performed in a manner similar to the regular looping step. It is noted that the wire “wd” paid out after forming the dummy bonding “dbp1” on the positioning pattern 26, which is not used for regular bonding connections, bears no relation to inconveniences such as shorting.

Next, as shown in FIG. 9, the controller 10 provides a drive signal to the XY table 12 and the bonding head 13 to form a dummy bonding “dbp2” on the positioning pattern 26 in a manner similar to the regular stitch bonding step to the second bonding position. Thus performing the dummy bonding step (g) causes the energy remaining in the wire tip portion to attenuate to the threshold value Eth or lower. As a result, when putting thereafter the capillary 15 back to the position of the pad 23c to connect the pad 23c and the lead frame 24c through the wire “wc”, the deformed ball “db1” bonded to the first bonding position has an appropriate diameter of D0, which achieves a common bonding process with no inconvenience.

In the embodiment above, the step of forming the dummy bonding “dbp2” included in the dummy bonding step (g) corresponds to the second (stitch) bonding step. However, from the viewpoint of productivity improvement, the dummy bonding step (g) can preferably exclude the two steps, the wire looping step (c) and the stitch bonding step (d), and include only the ball forming step (a) and the first (ball) bonding step (b).

It is noted that since the residual energy transfers from the ball in the wire tip portion to the dummy bonding surface as heat during the dummy bonding step (g), there is preferably no need to wait until the prohibition period shown in FIG. 6 has elapsed. If the prohibition period has not yet elapsed when the dummy bonding step (g) has ended, the process can preferably wait until the prohibition period has elapsed to go to the next ball forming step (a).

The dummy bonding surface to perform the dummy bonding step (g) thereon is not limited to the positioning pattern 26 as long as being a metal surface other than the regular bonding target surface. The surface can be, for example, a metal pattern bearing no relation to positioning, such as a portion of the lead frame 24 or another empty space on the substrate. Since the dummy bonding step (g) is performed during a break period after one wire bonding process (A) and before the next wire bonding process (A), it is preferable to shorten the travel distance of the capillary 15. It is therefore preferable to use a metal surface as close to the break position as possible as the dummy bonding surface to improve the productivity.

(Second Solution)

The second solution can be, in the wire bonding process (A), to perform the ball forming step (a), the first (ball) bonding step (b), the wire looping step (c), the second (stitch) bonding step (d), and the wire cutting step (e) in this order and, in the cleaning process, to perform the ball forming step (a) and the bonding tool cleaning step (f) in this order.

The energy of the plasma irradiation in the bonding tool cleaning step (f) is much lower than the energy of the spark when forming the ball “fab”. The wire tail “wt”, once melted and recrystallized into the ball “fab” instantaneously by the spark from the torch electrode 14, cannot be melted again even if plasma can be applied to the ball “fab”. For this reason, once the ball “fab” is formed in the tip portion of the wire “w” through the ball forming step (a), the diameter of the ball “fab” cannot be increased even if plasma can be applied to the ball “fab” thereafter. In accordance with the second solution, there is no need to wait until the residual energy of the plasma irradiation attenuates, which cannot deteriorate the productivity.

(Third Solution)

The third solution can be to perform the bonding tool cleaning step (f) and thereafter, at least for a prohibition period, to prohibit the ball forming step (a) of the next wire bonding process (A).

It is preferable to perform the ball forming step (a) after the prohibition period has elapsed because the ball “fab”, if formed during the prohibition period, can have an inconveniently large size. The third aspect has the advantage that there is no need to make settings for irregular process management such as dummy bonding and/or cleaning after ball forming to be described hereinafter, though it is necessary to wait until the prohibition period has elapsed.

### 3. Specific Implementations to which the Principle of Solutions is Applied

First to third embodiments will hereinafter be described specifically in which the respective first to third solutions are applied to the bonding apparatus 1.

### (1) First Embodiment

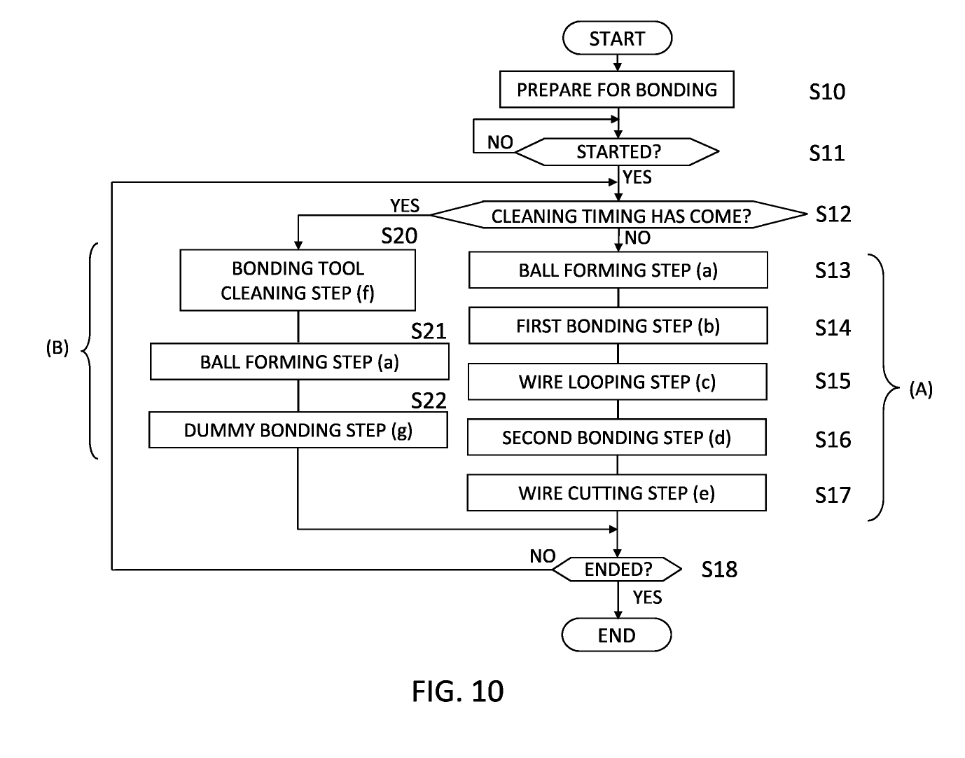

FIG. 10 is a flowchart illustrating a bonding tool cleaning method according to the first embodiment to which the first solution is applied. At the beginning, the cleaning flag indicating that it is immediately after the cleaning process is reset.

In step S10, a preparation is made for a bonding process. Correspondingly to operations on the operation unit 40 by the operator as mentioned above, the controller 10 records the movement trajectory of the capillary 15. When the semiconductor die 22 die bonded to the lead frame 24 is placed on the feeder 20, the controller 10 provides a control signal to heat the heater 21 to a predetermined temperature.

In step S11, after waiting for an instruction for starting the bonding process (NO), when the bonding process starting instruction is made (YES), the process goes to step S12 and the controller 10 determines whether or not the cleaning timing has come. The cleaning timing is preset as an adequate frequency to remove foreign matters based on the specifications of the bonding apparatus and/or the contamination conditions of the bonding target as mentioned above.

If the cleaning timing has not come (NO), the process goes to step S13 and the controller 10 performs the ball forming step (a). As illustrated with reference to FIGS. 3A and 3B, the controller 10 generates spark between the torch electrode 14 and the wire tail “wt” and, with the heat of the spark, forms a ball “fab” at the tip of the wire “w”.

The process then goes to step S14 and the controller 10 performs the first (ball) bonding step (b). As illustrated with reference to FIGS. 3C to 3E, for the first (ball) bonding step to the first bonding position, the controller 10 lowers the capillary 15 with the ball “fab” formed at the tip thereof toward the center of the pad 23 on the semiconductor die 22 and, applying ultrasonic vibration, bonds the ball “fab” onto the pad 23 to form a deformed ball “db1” at the first bonding position.

The process then goes to step S15 and the controller 10 performs the wire looping step (c). As illustrated with reference to FIGS. 4A to 4C, the controller 10 closes the wire clamper 17 and moves the capillary 15 in the direction against the second bonding position, and then opens the wire clamper 17 to pay out the wire “w”, following which closes the wire clamper 17 again and moves the capillary 15 to the second bonding position. In this step, a wire loop is thus formed.

The process then goes to step S16 and the controller 10 performs the second (stitch) bonding step (d) and the wire cutting step (e). As illustrated with reference to FIGS. 4D and 4E, the controller 10 moves the spatial position of the capillary 15 toward the lead frame 24 and, applying ultrasonic vibration, bonds the wire “w” onto the lead frame 24, and then performs the wire cutting step of cutting the wire “w” from the second bonding position to form “bp2” at the second bonding position.

The process then goes to step S18 and the controller 10 determines whether or not to end the wire bonding process. As long as it is determined to continue the wire bonding process (NO in step S18) and that the cleaning timing has not come (NO in step S12), the ball forming step (a) (step S13), the first (ball) bonding step (b) (step S14), the wire looping step (c) (step S15), the second (stitch) bonding step (d) (step S16), and the wire cutting step (e) (step S17) are repeated.

If it is determined in step S12 that the cleaning timing has come (YES), the process goes to step S20 and the controller 10 performs the bonding tool cleaning step (f). As illustrated with reference to FIGS. 5A and 5B, the controller 10 moves the capillary 15 to directly above the plasma torch 33 of the plasma irradiation device 30. Plasma 39 is then applied to the tip portion of the capillary 15 to remove organic foreign matters d2 adhering to the tip portion of the capillary 15. The controller applies ultrasonic vibration to the capillary 15 as appropriate.

After the bonding tool cleaning step (f), the process goes to step S21 and the controller 10 performs the ball forming step (a) as usual. The ball “fab” formed in this case has a size greater than usual under the influence of the residual energy of the plasma irradiation. Hence, the process goes to step S22 and the controller 10 performs the dummy bonding step (g). As shown in FIG. 7, the controller 10 moves the capillary 15 to the positioning pattern 26 for the semiconductor die 22 and, as shown in FIG. 8, forms a dummy bonding “dbp1” and a dummy bonding “dbp2” according to the dummy bonding step.

After the dummy bonding step (g), the process goes to step S18 and as long as it is determined to continue the wire bonding process (NO in step S18), the wire bonding process (A) (steps S13 to S17) is repeated until the next cleaning timing has come (NO in step S12).

In accordance with the first embodiment, when the ball forming step (a) is performed immediately after the bonding tool cleaning step (f), the ball “fab” is bonded onto the positioning pattern 26, which is not a regular bonding target surface. It is therefore possible to continue the bonding process without waiting until the residual energy of the plasma irradiation attenuates, which cannot deteriorate the productivity. Even if the bonding tool cleaning step (f) can be inserted irregularly or regularly in the repeated wire bonding processes (A) from the ball forming step (a) to the wire cutting step (e), the rhythm of the repetition of the steps cannot be disrupted. It is also possible to restart the regular ball forming step (a) immediately after the prohibition time has elapsed, which can improve the productivity.

### (2) Second Embodiment

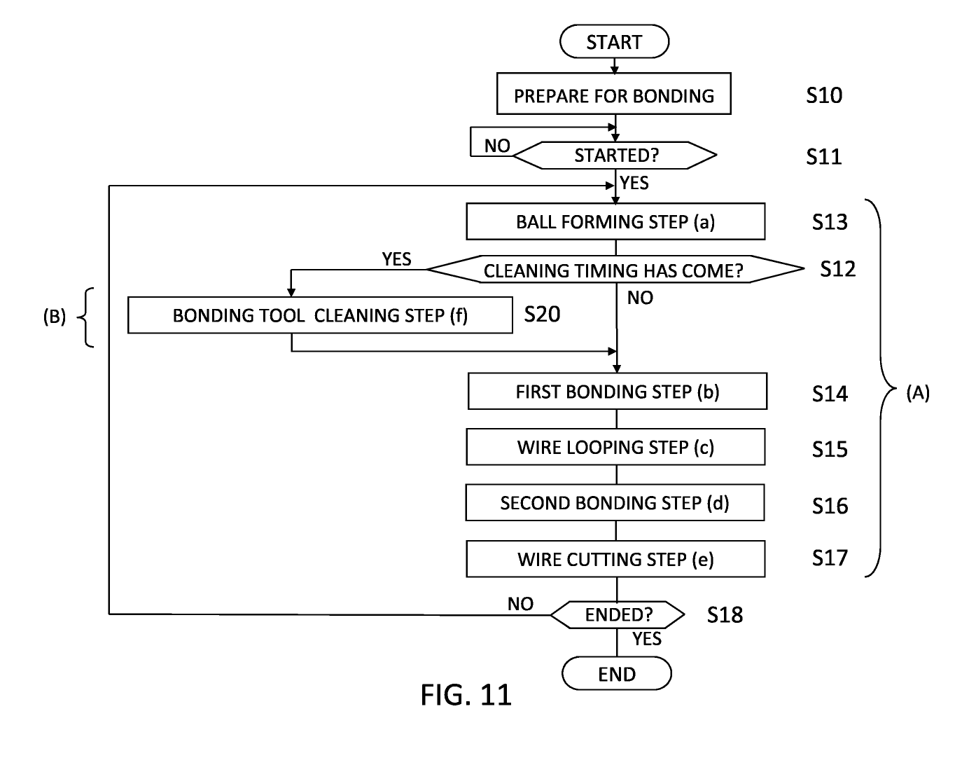

FIG. 11 is a flowchart illustrating a bonding tool cleaning method according to the second embodiment to which the second solution is applied.

In step S10, a preparation is made for a bonding process. Correspondingly to operations on the operation unit 40 by the operator as mentioned above, the controller 10 records the movement trajectory of the capillary 15. When the semiconductor die 22 die bonded to the lead frame 24 is placed on the feeder 20, the controller 10 provides a control signal to heat the heater 21 to a predetermined temperature.

In step S11, after waiting for an instruction for starting the bonding process (NO), when the bonding process starting instruction is made (YES), the process goes to step S13 and the controller 10 performs the ball forming step (a). The controller 10 generates spark between the torch electrode 14 and the wire tail “wt” and, with the heat of the spark, forms a ball “fab” at the tip of the wire “w”.

The process then goes to step S12 and the controller 10 determines whether or not the cleaning timing has come. If it is determined that the cleaning timing has not come (NO), the controller 10 performs the first (ball) bonding step (b) in step S14, the wire looping step (c) in step S15, the second (stitch) bonding step (d) in step S16, and the wire cutting step (e) in step S17.

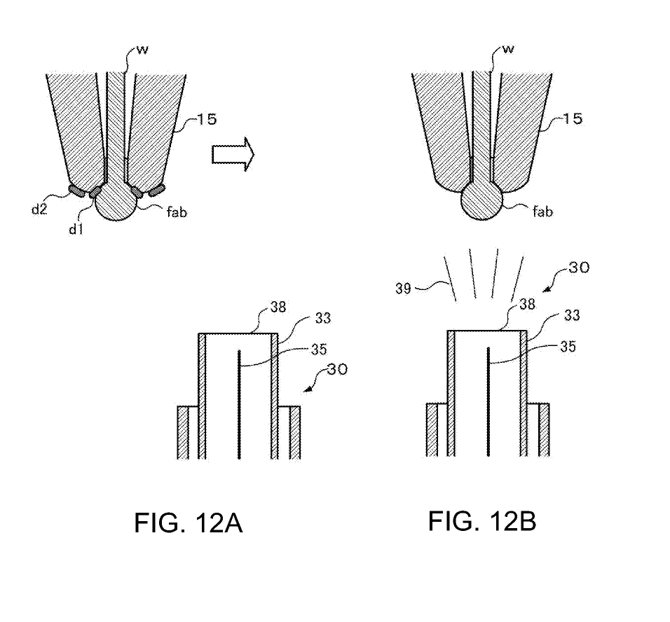

In contrast, if it is determined in step S12 that the cleaning timing has come (YES), the process goes to step S20 and the controller 10 performs the bonding tool cleaning step (f). That is, as shown in FIG. 12A, the controller 10 moves the capillary 15 with the ball “fab” formed thereon to directly above the plasma torch 33 of the plasma irradiation device 30. As shown in FIG. 12B, ionized plasma 39 is then applied to the tip portion of the capillary 15 to remove organic foreign matters d2 adhering to the tip portion of the capillary 15. The controller 10 applies ultrasonic vibration to the capillary 15 as appropriate. Even if the ball “fab” is formed at the tip of the wire “w”, the recrystallization of the ball “fab” is completed and thereby the size of the ball “fab” remains usual without being increased by the energy of the plasma irradiation.

After the bonding tool cleaning step (g), the controller 10 performs the first (ball) bonding step (b) in step S14, the wire looping step (c) in step S15, the second (stitch) bonding step (d) in step S16, and the wire cutting step (e) in step S17. Since the ball “fab” in this case has a usual size, the deformed ball bonded to the first bonding position to be formed also has a usual diameter.

The process then goes to step S18 and the controller 10 determines whether or not to end the wire bonding process. If it is determined not to end the bonding process (NO), the process goes back to step S13 again. In contrast, if it is determined in step S18 to end the bonding process (YES), the bonding operation is terminated.

In accordance with the second embodiment, it is possible to perform the first (ball) bonding step (b), the wire looping step (c), the second (stitch) bonding step (d), and the wire cutting step (e) without waiting until the residual energy of the plasma irradiation attenuates, which cannot deteriorate the productivity.

### (3) Third Embodiment

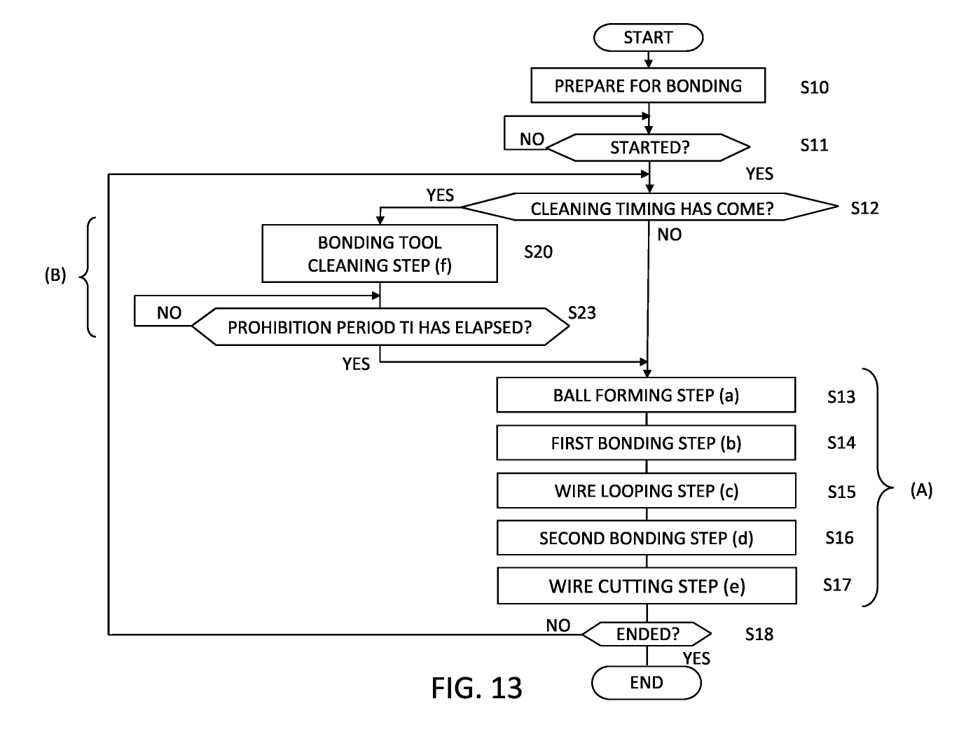

FIG. 13 is a flowchart illustrating a bonding tool cleaning method according to the third embodiment to which the third solution is applied.

In step S10, a preparation is made for a bonding process. Correspondingly to operations on the operation unit 40 by the operator as mentioned above, the controller 10 records the movement trajectory of the capillary 15. When the semiconductor die 22 die bonded to the lead frame 24 is placed on the feeder 20, the controller 10 provides a control signal to heat the heater 21 to a predetermined temperature.

In step S11, after waiting for an instruction for starting the bonding process (NO), when the bonding process starting instruction is made (YES), the process goes to step S12 and the controller 10 determines whether or not the cleaning timing has come.

As long as it is determined that the cleaning timing has not come (NO in step S12), the controller 10 performs the ball forming step (a) in step S13, the first (ball) bonding step (b) in step S14, the wire looping step (c) in step S15, the second (stitch) bonding step (d) in step S16, and the wire cutting step (e) in step S17.

In contrast, if it is determined in step S12 that the cleaning timing has come (YES), the process goes to step S20 and the controller 10 performs the bonding tool cleaning step (f). That is, the controller 10 moves the capillary 15 to directly above the plasma torch 33 of the plasma irradiation device 30. Ionized plasma 39 is then applied to the tip portion of the capillary 15 to remove organic foreign matters d2 adhering to the tip portion of the capillary 15. The controller 10 applies ultrasonic vibration to the capillary 15 as appropriate.

After the bonding tool cleaning step (g), the process goes to step S23 and the controller 10 determines whether or not the prohibition period Ti has elapsed. If it is determined that the prohibition period Ti has not elapsed (NO), the standby continues. The energy of the plasma irradiation remaining in the wire tip portion attenuates during the standby.

If it is determined in step S23 that the prohibition period Ti has elapsed (YES), the controller 10 again performs the steps (S13 to S17) of the wire bonding process (A). In step S18, the controller 10 determines whether or not to end the bonding process. If it is determined not to end the bonding process (NO), the process goes back to step S12 again. After the prohibition period Ti has elapsed, the residual energy in the wire tip portion has attenuated to a level not having an impact on the diameter of the ball “fab” to be formed, so that there is no problem to perform the ball forming step (a) of the next wire bonding process (A).

In contrast, if it is determined in step S18 to end the bonding process (YES), the bonding operation is terminated.

The third embodiment has the advantage that there is no need to make settings for irregular process management such as dummy bonding and/or cleaning after ball forming, though it is necessary to wait until the prohibition period Ti has elapsed.

### (4) Other Embodiments

The present invention is not limited to the above-described embodiments, and can also be applied with various modifications added thereto.

For example, the first to third solutions can be applied in combination. Specifically, in the first embodiment to which the first solution is applied, when the dummy bonding step (g) is completed but the prohibition period Ti has not yet elapsed after the plasma irradiation in the bonding tool cleaning step (f), the third solution can be applied to wait until the prohibition period Ti has elapsed to perform the next ball forming step (a). Alternatively, the dummy bonding step (g) can be repeated if the prohibition period Ti has not elapsed.

Also, in the second embodiment to which the second solution is applied, when the ball forming step (a), the bonding tool cleaning step (f), and the first (ball) bonding step (b) are completed in this order but the prohibition period Ti has not yet elapsed after the plasma irradiation in the bonding tool cleaning step (f), the third solution can be applied to wait until the prohibition period Ti has elapsed to perform the next ball forming step (a).

The steps (a) to (e) of the wire bonding process (A) are illustrated only as a typical example and the details of the process can be applied with a modification added thereto as appropriate. For example, the wire looping step (c) can not necessarily be such looping as shown in FIGS. 4A to 4C, but the capillary 15 can be moved along a different trajectory to form the wire “w” into a desired loop.

### INDUSTRIAL APPLICABILITY

The present invention is applicable not only to bonding tool cleaning in bonding apparatuses but also to cleaning methods in other types of apparatuses that utilize plasma irradiation, particularly in the case where it is necessary to insert a plasma-based cleaning step regularly or irregularly in a predetermined routine process and the energy of plasma irradiation can have a negative impact on the routine process.

### DESCRIPTION OF NUMERALS

D0-2 diameter,
HS high-frequency signal
HV high voltage
PO width
Ti prohibition period
db1 deformed ball
bp1, bp2 bonding point
d1 metallic foreign matter
d2 organic foreign matter
dbp1 dummy bonding point
dp1 bonding point
fab ball
w, wa-d wire
wt wire tail
1 bonding apparatus
10 controller
11 base
12 XY table
13 bonding head
14 torch electrode
15 capillary
16 bonding arm
17 wire clamper
18 wire tensioner
19 rotary spool
20 feeder
21 heater
22 semiconductor chip
23 pad
24 lead frame
26 positioning pattern
30 plasma irradiation device
31 gas chamber
32 high-frequency signal generator
33 plasma torch
34 load electrode
35 grounding electrode
36 gas pipe
37 shutoff valve
38 opening
39 plasma
40 operation unit
41 display
42 camera
151 straight hole
152 chamfer portion
153 face portion
154 outer-radius portion
155 outer peripheral surface
161 ultrasonic transducer

1. A method of cleaning a bonding tool of a bonding apparatus,
the bonding apparatus comprising
a discharge device for forming a free-air ball at a tip of a wire;
the bonding tool for bonding the free-air ball formed at a tip of the wire to a first bonding position;
a plasma irradiation device for performing plasma irradiation to clean the bonding tool;
a controller for controlling the discharge device, the bonding tool, and the plasma irradiation device,
the method comprising:
(a) forming the free-air ball at the tip of the wire extending out from a tip of the bonding tool;
(b) bonding the free-air ball formed at the tip of the wire extending out from the tip of the bonding tool to the first bonding position with the bonding tool to form a deformed ball;
(c) looping the wire toward a second bonding position along a predetermined trajectory of the bonding tool while paying out the wire from the tip of the bonding tool;
(d) bonding the wire extending out from the tip of the bonding tool to the second bonding position; and
(e) the bonding tool while paying out the wire from the tip of the bonding tool and, upon reaching a predetermined height, closing a clamper to cut the wire from the second bonding position, so that appropriate length of the wire extends out from the tip of the bonding tool,
(f) cleaning the bonding tool through plasma irradiation after performing steps (a)-(e), and
(g) bonding the free-air ball formed at the tip of the wire to a dummy bonding position.

2. The bonding method according to claim 1,
wherein, after step (g), a step (h) is performed,
wherein step (h) is raising the bonding tool while paying out the wire from the tip of the bonding tool and, upon reaching a predetermined height, closing a clamper to cut the wire from the dummy bonding position, so that appropriate length of the wire extends out from the tip of the bonding tool, and
wherein steps (a)-(e) are performed after step (h).

3. The method according to claim 1,
wherein the dummy bonding position is a positioning pattern.

4. A method of cleaning a bonding tool of a bonding apparatus,
the bonding apparatus comprising
a discharge device for forming a free-air ball at a tip of a wire;
the bonding tool for bonding the free-air ball formed at a tip of the wire to a first bonding position;
a plasma irradiation device for performing plasma irradiation to clean the bonding tool;
a controller for controlling the discharge device, the bonding tool, and the plasma irradiation device,
the method comprising:
(a) forming the free-air ball at the tip of the wire extending out from a tip of the bonding tool;
(b) bonding the free-air ball formed at the tip of the wire extending out from the tip of the bonding tool to the first bonding position with the bonding tool to form a deformed ball;
(c) looping the wire toward a second bonding position along a predetermined trajectory of the bonding tool while paying out the wire from the tip of the bonding tool;
(d) bonding the wire extending out from the tip of the bonding tool to the second bonding position; and
(e) the bonding tool while paying out the wire from the tip of the bonding tool and, upon reaching a predetermined height, closing a clamper to cut the wire from the second bonding position, so that appropriate length of the wire extends out from the tip of the bonding tool, and
(f) cleaning the bonding tool through plasma irradiation after performing steps (a)-(e),
wherein, after step (f), the step (a) is performed at least after a prohibition period during which energy of the plasma irradiation attenuates.

5. The method according to claim 4,
wherein the prohibition period is a period, after the plasma irradiation, during which the increase in the diameter of the free-air ball by the energy of the plasma irradiation becomes substantially unobservable.

6. The method according to claim 1,
wherein steps (a)-(e) are performed in sequence a predetermined number of times before steps (f) and (g) are performed.

7. The method according to claim 4,
wherein steps (a)-(e) are performed in sequence a predetermined number of times before step (f) is performed.

8. A method of cleaning a bonding tool of a bonding apparatus,
the bonding apparatus comprising
a discharge device for forming a free-air ball at a tip of a wire;
the bonding tool for bonding the free-air ball formed at a tip of the wire to a first bonding position;
a plasma irradiation device for performing plasma irradiation to clean the bonding tool;
a controller for controlling the discharge device, the bonding tool, and the plasma irradiation device,
the method comprising:
(a) forming the free-air ball at the tip of the wire extending out from a tip of the bonding tool;
(b) bonding the free-air ball formed at the tip of the wire extending out from the tip of the bonding tool to the first bonding position with the bonding tool to form a deformed ball;
(c) looping the wire toward a second bonding position along a predetermined trajectory of the bonding tool while paying out the wire from the tip of the bonding tool;
(d) bonding the wire extending out from the tip of the bonding tool to the second bonding position; and
(e) the bonding tool while paying out the wire from the tip of the bonding tool and, upon reaching a predetermined height, closing a clamper to cut the wire from the second bonding position, so that appropriate length of the wire extends out from the tip of the bonding tool, and
(f) cleaning the bonding tool through plasma irradiation after performing steps (a)-(e),
wherein, after steps (a)-(e) are performed in sequence a predetermined number of times, step (a) is performed, thereafter step (f) is performed, and
wherein steps (a)-(e) are performed after step (f).
